(19) United States
(12) Patent Application Publication
(10) Pub. No.: US 2023/0125309 A1
(43) Pub. Date: Apr. 27, 2023

(54) SEMICONDUCTOR DEVICE AND METHOD FOR PREPARING SAME

(71) Applicant: YANGTZE MEMORY TECHNOLOGIES CO., LTD., Wuhan (CN)

(72) Inventors: Simin Liu, Wuhan (CN); Wei Xu, Wuhan (CN); Bo Xu, Wuhan (CN); Yali Guo, Wuhan (CN)

(21) Appl. No.: 18/087,159

(22) Filed: Dec. 22, 2022

Related U.S. Application Data
(63) Continuation of application No. PCT/CN2021/130905, filed on Nov. 16, 2021.

(30) Foreign Application Priority Data
Nov. 18, 2020 (CN) 202011294003.2

(51) Int. Cl. H10B 43/27; H10B 43/10; H10B 41/10; H10B 41/27

(52) U.S. Cl. CPC H10B 43/27; H10B 43/10; H10B 41/10; H10B 41/27

(57) ABSTRACT

A semiconductor device includes: a substrate; stacked layers on the substrate including insulating layers and gate layers that are alternately stacked in a longitudinal direction and extending in a first lateral direction and a second lateral direction; a channel column array including a plurality of channel columns in the stacked layers; a dummy channel column array including a plurality of dummy channel columns in the stacked layers; and a gate isolating trench in the stacked layers, the gate isolating trench extends between the channel column array and the dummy channel column array along the second lateral direction. The first lateral direction and the second lateral direction are perpendicular to each other and are both perpendicular to the longitudinal direction.

### CROSS-REFERENCE TO RELATED APPLICATIONS

This application is a continuation of International Application No. PCT/CN2021/130905 filed on Nov. 16, 2021, which claims the benefit of priority to Chinese Application No. 202011294003.2 filed on Nov. 18, 2020, the entire contents of which are hereby incorporated by reference in their entireties.

### BACKGROUND

A memory is a memory device used to store information in modern information technology. With electronic devices having constantly increasing demands for the integration degree and data storage density, it is becoming more and more difficult for an ordinary two-dimensional storage device to be satisfactory. In this situation, three-dimensional (3D) memory has emerged.

In preparing a three-dimensional memory, a stacked structure is mainly formed on a substrate, and the stacked structure is divided into a core region and a stair-step region in the plane direction of the substrate. In the core region and the stair-step region, several channel holes (CHs) will be provided and filled with corresponding materials to realize the storage function and supporting function.

In order to reduce the processing difficulty, the channel holes in the core region are first formed, and the channel holes in the stair-step region are formed thereafter. However, since the channel holes in the core region are first formed by etching and are filled, there will be charges stored in the channel holes in the core region. When etching the channel holes in the stair-step region, the charges in the channel holes in the core region will have an attraction force on the channel holes in the stair-step region, which results in the deformation of the channel holes in the stair-step region. Such deformation may cause leakage current of the semiconductor device and affect the performance of the device.

### SUMMARY

The implementations of the present disclosure relate to the technical field of semiconductors, and in particular to a semiconductor device and a method for preparing same.

The semiconductor device includes stacked layers, a channel column array, a dummy channel column array, and a gate isolating trench.

The stacked layers include insulating layers and gate layers that are alternately stacked along a longitudinal direction and extending in a first lateral direction and a second lateral direction. The first lateral direction and the second lateral direction are perpendicular to each other and are both perpendicular to the longitudinal direction.

The channel column array is formed in the stacked layers, and includes multiple channel columns arranged in an array in the first lateral direction and in the second lateral direction.

The dummy channel column array is formed in the stacked layers, and includes multiple dummy channel columns arranged in an array in the first lateral direction and the second lateral direction.

The gate isolating trench is formed in the stacked layers, extends along the second lateral direction, and is formed between the channel column array and the dummy channel column array.

In another aspect, the implementations of the present disclosure further provide a method for preparing a semiconductor device. The method includes the following steps.

A substrate is provided.

Stacked layers are formed. The stacked layers are formed on the substrate by alternately stacking insulating layers and gate layers along a longitudinal direction, where the insulating layers and gate layers extend along a first lateral direction and a second lateral direction. The first lateral direction and the second lateral direction are perpendicular to each other and are both perpendicular to the longitudinal direction.

A channel column array is formed. The channel column array is formed in the stacked layers, and includes multiple channel columns arranged in an array in the first lateral direction and in the second lateral direction.

A dummy channel column array is formed. The dummy channel column array is formed in the stacked layers, and includes multiple dummy channel columns arranged in an array in the first lateral direction and the second lateral direction.

A gate isolating trench is formed. The gate isolating trench is formed in the stacked layers, extending along the second lateral direction, and is formed between the transition channel column array and the dummy channel column array.

### BRIEF DESCRIPTION OF THE DRAWINGS

In order to explain the technical solutions in the implementations of the present disclosure more clearly, the following will briefly introduce the drawings used in the description of various implementations of the present disclosure. The drawings in the following description are only some implementations of the present disclosure. For those skilled in the art, other drawings can be obtained according to these drawings without creative effort.

FIG. 1 illustrates a schematic structural top view of a semiconductor device provided in a first implementation of the present disclosure.

FIG. 2 illustrates a schematic structural front view of the semiconductor device provided in the first implementation of the present disclosure.

FIG. 3 illustrates a schematic flowchart of a method for preparing a semiconductor device provided in the first implementation of the present disclosure.

FIG. 4 illustrates a schematic structural top view of a semiconductor device provided in a second implementation of the present disclosure.

FIG. 5 illustrates a schematic structural front view of the semiconductor device provided in the second implementation of the present disclosure.

### DETAILED DESCRIPTION

The technical solutions in the implementations of the present disclosure will be clearly described below in conjunction with the drawings in the implementations of the present disclosure. The described implementations are only some rather than all the implementations. Based on the implementations of the present disclosure, all other implementations obtained by those skilled in the art without creative effort shall fall within the protection scope of the implementations of the present disclosure.

In the description of the implementations of the present disclosure, it should be understood that the orientation or positional relationship indicated by the terms “center,” “longitudinal,” “lateral,” “length,” “width,” “thickness,” “upper,” “lower,” “front,” “rear, ” “left,” “right,” “vertical, ” “horizontal,” “top,” “bottom,” “inner,” “outer,” “clockwise,” “counterclockwise” is based on the orientation or positional relationship illustrated in the drawings, and the terms are only used to facilitate the description of the implementations of the present disclosure and simplify the description, and do not indicate or imply that the apparatus or element referred to must have a specific orientation, or be constructed or operated in a specific orientation, and thus cannot be construed as limitations to the implementations of the present disclosure. In addition, the terms “first” and “second” are only used for describing objectives, and cannot be understood as indicating or implying relative importance or implicitly indicating the number of indicated technical features. Therefore, the features defined with “first” and “second” may explicitly or implicitly include one or more of the features. In the description of the implementations of the present disclosure, “a plurality of/multiple” means two or more, unless otherwise specifically defined.

In the description of the implementations of the present disclosure, it should be noted that, unless otherwise clearly specified and limited, the terms “installation,” “interconnection,” and “connection” should be understood in a broad sense, for example, it may be a fixed connection or detachable connection, or integral connection; it may be a mechanical connection, or may be an electrical connection or may be mutual communication; it may be a direct connection or an indirect connection through an intermediate medium, or may be the internal communication of two elements or the interaction between the two elements. For a person of ordinary skill in the art, the specific meanings of the above terms in the implementations of the present disclosure may be understood according to specific situations.

In the implementations of the present disclosure, unless expressly stipulated and defined otherwise, a first feature being on or “under” a second feature may include direct contact between the first and second features, or may include the first and second features being not in direct contact but through another feature between them. Moreover, a first feature being “above,” “over,” and “on” a second feature include the first feature being directly above/over/on the second feature and the first feature being obliquely above/over/on the second feature, or merely indicating that the horizontal height of the first feature is higher than that of the second feature. The first feature being “below,” “under,” and “underneath” the second feature include the first feature being directly below/under/underneath the second feature and the first feature being obliquely below/under/underneath the second feature, or merely indicating that the horizontal height of the first feature is lower than that of the second feature.

The following disclosure provides many different implementations or examples for realizing different structures of the implementations of the present disclosure. In order to simplify the disclosure, the components and settings of specific examples are described below. They are only examples, and are not intended to limit the implementations of the present disclosure. In addition, reference numbers and/or reference letters may be repeated in different examples of the implementations of the present disclosure, and such repetition is for the objective of simplification and clarity, and does not indicate the relationship between the various implementations and/or settings discussed. In addition, the implementations of the present disclosure provide examples of various specific processes and materials, hut a person of ordinary skill in the art may be aware of the application of other processes and/or the use of other materials.

The implementations of the present disclosure are directed to solve the problem in existing semiconductor devices that channel columns in a stair-step region are deformed due to the attraction force of channel columns in a core region, resulting in a leakage current in the semiconductor device and affecting the performance of the semiconductor device.

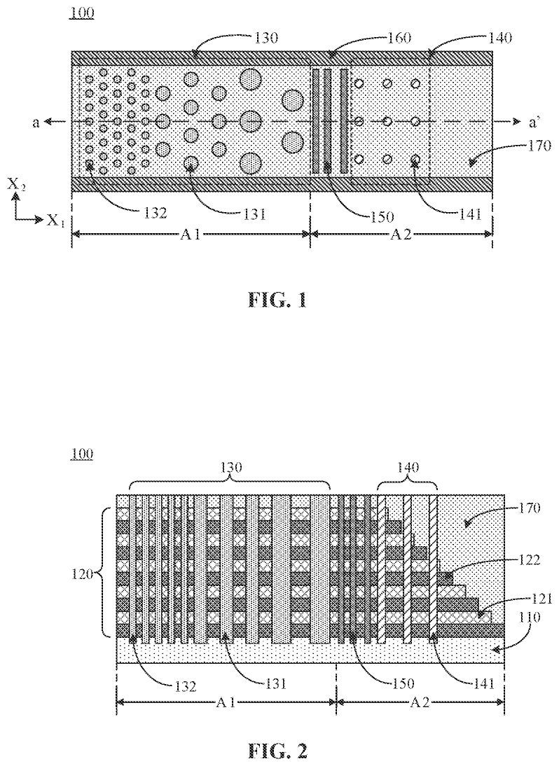

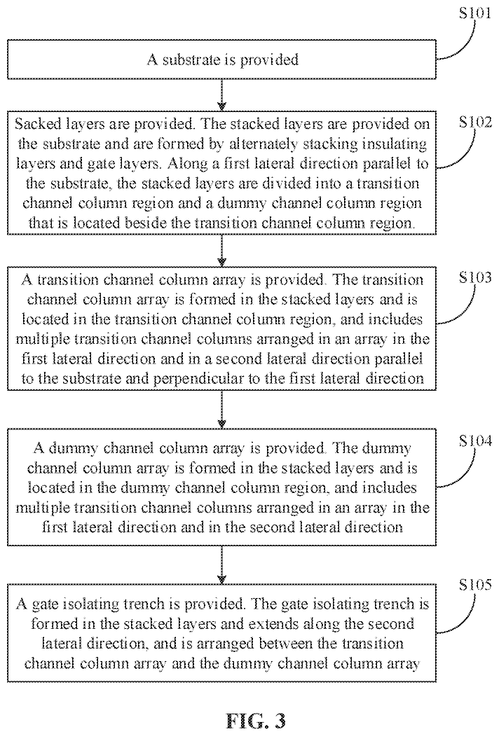

FIG. 1 illustrates a schematic structural top view of a semiconductor device 100 provided in a first implementation of the present disclosure, and FIG. 2 illustrates a schematic structural front view of the semiconductor device 100 provided in the first implementation of the present disclosure. The schematic structural front view is a cross-sectional schematic diagram cut along aa′ of the schematic structural top view as illustrated in FIG. 1. From the drawings, the parts according to the implementations of the present disclosure and the relative position relationship of the parts can be seen intuitively.

As illustrated in FIGS. 1 and 2, the semiconductor device 100 includes a substrate 110, stacked layers 120, a channel column array 130, a dummy channel column array 140, a gate isolating trench 150, and a dielectric layer 170 disposed on the stacked layers 120.

The substrate 110 may be a semiconductor substrate, including at least one elementary-element semiconductor material (for example, a silicon (Si) substrate, or a germanium (Ge) substrate), at least one III-V compound semiconductor material, at least one II-VI compound semiconductor material, at least one organic semiconductor material, or other semiconductor materials known in the art.

The stacked layers 120 are disposed on the substrate 110 and are formed by alternately stacking insulating layers 121 and gate layers 122. The insulating layers 121 are made of an insulating material, including but not limited to silicon oxide, silicon nitride, silicon oxynitride, or a combination thereof. The gate layers 122 are made of a conductive material, including but not limited to wolfram (W), cobalt (Co), copper (Cu), aluminum (Al), doped silicon, silicide, or a combination thereof. In some implementations, along the first lateral direction X₁ parallel to the substrate 110, the stacked layers 120 are divided into a channel column region A1 and a dummy channel column region A2 located beside the channel column region A1.

The channel column array 130 is formed in the stacked layers 120, is located in the channel column region A1, and includes multiple transition channel columns 131 and multiple storage channel columns 132 arranged in an array in a first lateral direction X₁ and a second lateral direction X₂ parallel to the substrate 110 and perpendicular to the first lateral direction X₁.

In some implementations, a functional layer and a channel layer are sequentially formed on the inner wall of the transition channel columns 131 and the inner wall of the storage channel columns 132. However, the transition channel columns 131 only play a supporting role and have no storage function, while the storage channel columns 132 have a storage function. For example, the storage channel columns 132 are connected to a peripheral circuit to receive a control signal from the peripheral circuit to realize the storage function. The functional layer includes a tunneling dielectric layer, a charge storage layer, and a gate dielectric layer which are stacked. Exemplary materials for the gate dielectric layer and the tunneling dielectric layer may be silicon oxide, silicon nitride, an insulating material with a high insulation constant, or a combination thereof Exemplary materials for the charge storage layer may be silicon nitride, silicon oxynitride, silicon, or a combination thereof.

In the implementations of the present disclosure, the material filled in the transition channel columns 131 is not limited, in some implementations, the material filled in the transition channel columns 131 may be filled together with the functional layer and the channel layer filled in the storage channel columns 132. For example, filling the functional layer in the transition channel columns 131 and filling the functional layer in the storage channel columns 132 are completed in the same one or more process steps, and filling the channel layer in the transition channel columns 131 and filling the channel layer in the storage channel columns 132 are also completed in the same one or more process steps. In some implementations, the material filled in the transition channel columns 131 may be different from the material filled in the storage channel columns 132. For example, the mated al filled in the transition channel columns 131 may be silicon dioxide or other insulating materials, and the material filled in the storage channel columns 132 is a functional layer and a channel layer.

In some implementations, the channel column region A1 may contain storage channel columns 132, and the storage channel columns 132 may be adjacent to the gate isolating trench 150.

In some implementations, the transition channel columns 131 are located between the storage channel columns 132 and the dummy channel columns 141, and the critical dimension of the transition channel columns 131 is larger than the critical dimension of the storage channel columns 132. The critical dimension of a transition channel column 131 may be the distance from the center of the transition channel column 131 to the edge of the transition channel column 131, and the critical dimension of a storage channel column 132 may be the distance from the center of the storage channel column 132 to the edge of the storage channel column 132. The transition channel columns 131 have a larger critical dimension, and can provide a larger supporting area to improve the function of supporting the semiconductor device.

The dummy channel column array 140 is formed in the stacked layers 120 and located in the dummy channel column region A2, and includes multiple dummy channel columns 141 arranged in an array in the first lateral direction X₁ and the second lateral direction X2. In sonic implementations, the multiple dummy channel columns 141 are disposed in the stair-step region formed by the stacked layers 120. In some implementations, the dummy channel columns 141 play a supporting role. For example, the material filled in the dummy channel columns 141 may be silicon dioxide or other insulating materials.

The gate isolating trench 150 is formed in the stacked layers 120 and extends along the second lateral direction X2, and is disposed between the channel column array 130 and the dummy channel column array 140. In some implementations, the gate isolating trench 150 is located in the dummy channel column region A2.

In some implementations, as illustrated in FIG. 2, the gate isolating trench 150 includes multiple gate isolating trenches arranged at intervals along the first lateral direction X₁, and the arrangement density of the multiple gate isolating trenches gradually decreases in the direction from the channel column array 130 to the dummy channel column array 140.

In some implementations, the cross-sectional shape of the gate isolating trench 150 in the first lateral direction X₁ includes at least one of a rectangle, a trapezoid, or a semicircular shape. The cross-sectional shape is a shape close to the channel column region A1. A surface of the gate isolating trench 150 facing the dummy channel column array 140 is planar. In this implementation, as illustrated in FIG. 1, the cross-sectional shape of the gate isolating trench 150 in the first lateral direction X₁ is a rectangle.

In some implementations, continue to refer to FIG. 1. As illustrated in FIG. 1, the semiconductor device 100 further includes a gate line slit 160. The gate line slit 160 penetrates through the stacked layers 120 in a longitudinal direction perpendicular to the substrate 110 and extends along the first lateral direction X₁, and a material of the gate isolating trench 150 is same as a material of the gate line slit 160. Exemplary materials of the gate isolating trench 150 and the gate line slit 160 may be polysilicon and wolfram (W).

In this implementation, the gate isolating trench 150 separates the channel column array 130 from the dummy channel column array 140, and the two surfaces of the gate isolating trench respectively facing the channel column array 130 and the dummy channel column array 140 are completely planar. Such a design can better resist the attraction force of the charges in the functional layer of the transition channel columns 131 to the gate isolating trench 150 and the dummy channel columns 141. Therefore, the deformation of the gate isolating trench 150 and the dummy channel column 141 is avoided. The leakage current in the semiconductor device 100 will be reduced, and the performance of the semiconductor device 100 is improved.

In some implementations, in order to prevent a sudden change in the attraction force of the charges in the functional layer of the transition channel columns 131, the density of the transition channel columns 131 in the channel column array 130 gradually decreases towards the dummy channel column region A2 alone the first lateral direction X₁. Moreover, each transition channel column 131 has a critical dimension (CD), which is the distance from the center of the transition channel column 131 to the edge of the transition channel column 131, and the critical dimensions of the transition channel columns 131 gradually increase towards the dummy channel column region A2 along the first lateral direction X₁.

FIG. 3 illustrates a schematic flowchart of a method for preparing a semiconductor device 100 provided by a first implementation of the present disclosure.

As illustrated in FIG. 3, referring to the reference signs of the components constituting the semiconductor device 100 in FIG. 1 and FIG. 2, the method includes the following steps.

S101: a substrate 110 is provided.

S102: stacked layers 120 are formed. The stacked layers 120 are formed on the substrate 110 by alternately stacking insulating layers 121 and gate layers 122. Along a first lateral direction X₁ parallel to the substrate 110, the stacked layers 120 are divided into a transition channel column region Al and a dummy channel column region A₂ that is located beside the transition channel column region A1.

S103: a transition channel column array 130 is formed. The transition channel column array 130 is formed in the stacked layers 120 and is located in the transition channel column region A1, and includes multiple transition channel columns 131 arranged in an array in the first lateral direction X₁ and in a second lateral direction X₂ that is parallel to the substrate 110 and perpendicular to the first lateral direction X₁.

S104: a dummy channel column array 140 is formed. The dummy channel column array 140 is formed in the stacked layers 120 and is located in the dummy channel column region A2, and includes multiple dummy channel columns 141 arranged in an array in the first lateral direction X₁ and the second lateral direction X₂.

S105: a gate isolating trench 150 is formed. The gate isolating trench 150 is formed in the stacked layers 120 and extends along the second lateral direction X₂, and is arranged between the transition channel column array 130 and the dummy channel column array 140.

Different from the related art, the implementations of the present disclosure provide a semiconductor device 100. The semiconductor device 100 includes a substrate 110, stacked layers 120, a channel column array 130, a dummy channel column array 140, and a gate isolating trench 150. The stacked layers 120 are formed on the substrate 110 by alternately stacking insulating layers 121 and gate layers 122. Along a first lateral direction X₁ parallel to the substrate 110, the stacked layers 120 are divided into a channel column region A1 and a dummy channel column region A2 that is located beside the channel column region A1. The channel column array 130 and the dummy channel column array 140 are formed in the stacked layers 120 and respectively located in the channel column region A1 and the dummy channel column region A2. The channel column array 130 includes multiple transition channel columns 131 arranged in an array in the first lateral direction X₁ and a second lateral direction X₂ perpendicular to the first lateral direction X₁. The dummy channel column array 140 includes multiple dummy channel columns 141 arranged in an array in the first lateral direction X₁ and the second lateral direction X₂. The gate isolating trench 150 is formed in the stacked layers 120 and extends along the second lateral direction X₂, and is arranged between the channel column array 130 and the dummy channel column array 140. In the semiconductor device 100 according to the implementations of the present disclosure, by providing a gate isolating trench 150 between the channel column array 130 and the dummy channel column array 140, the problem that the dummy channel columns 141 are deformed due to the attraction force of the charges in the transition channel columns 131 to the dummy channel columns 141, resulting in the leakage current of the semiconductor device 100 and affecting the performance of the semiconductor device 100 is effectively avoided.

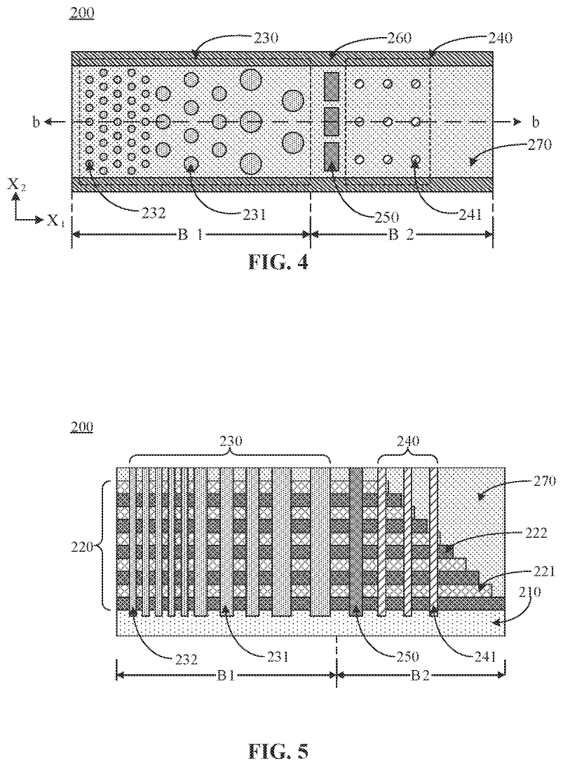

FIG. 4 illustrates a schematic structural top view of a semiconductor device 200 provided in a second implementation of the present disclosure, and FIG. 5 illustrates a schematic structural front view of the semiconductor device provided in the second implementation of the present disclosure. The schematic structural front view is a cross-sectional schematic diagram cut along bb′ of the schematic structural top view as illustrated in FIG. 4. From the drawings, the parts according to the implementations of the present disclosure and the relative position relationship of the parts can be seen intuitively.

As illustrated in FIG. 4, the structure of the second implementation is roughly the same as that of the first implementation. The function and arrangement position of the substrate 210 in the second implementation are the same as those of the substrate 110 in the first implementation. The function and arrangement position of the stacked layers 220 (including the insulating layers 221 and the gate layers 222 alternately stacked) in the second implementation are the same as those of the stacked layers 120 (including the insulating layers 121 and the gate layers 122 stacked alternately) in the first implementation. The function and arrangement position of the channel column array 230 (including multiple transition channel columns 231 and multiple storage channel columns 232) in the second implementation are the same as those of the channel column array 130 (including multiple transition channel columns 131 and multiple storage channel columns 132) in the first implementation. The function and arrangement position of the dummy channel column array 240 (including multiple dummy channel columns 241) in the second implementation is the same as those of the dummy channel column array 140 (including multiple dummy channel columns 141) in the first implementation. The function and arrangement of the gate line slit 260 in the second implementation are the same as those of the gate line slit 160 in the first implementation. The function and arrangement position of the dielectric layer 270 in the second implementation are the same as those of the dielectric layer 170 in the first implementation. The difference is that the arrangement of the gate isolating trench 250 in this implementation is different from the arrangement of the gate isolating trench 150 in the first implementation. In this implementation, as illustrated in FIG. 4, the gate isolating trench 250 includes multiple gate isolating trenches arranged at intervals along the second lateral direction X₂ to form a dotted line shape.

Different from the related art, the implementations of the present disclosure provide a semiconductor device 200. The semiconductor device 200 includes a substrate 210, stacked layers 220, a channel column array 230, a dummy channel column array 240, and a gate isolating trench 250. The stacked layers 220 are formed on the substrate 210 by alternately stacking insulating layers 221 and gate layers 222. Along a first lateral direction X₁ parallel to the substrate 210, the stacked layers 220 are divided into a channel column region B1 and a dummy channel column region B2 that is located beside the channel column region B1. The channel column array 230 and the dummy channel column array 240 are formed in the stacked layers 220 and respectively located in the channel column region B1 and the dummy channel column region B2. The channel column array 230 includes multiple transition channel columns 231 arranged in an array in the first lateral direction X1 and a second lateral direction X₂, perpendicular to the first lateral direction X₁. The dummy channel column array 240 includes multiple dummy channel columns 241 arranged in an array in the first lateral direction X1 and the second lateral direction X₂. The gate isolating trench 250 is formed in the stacked layers 220 and extends along the second lateral direction X₂, and is arranged between the channel column array 230 and the dummy channel column array 240. In the semiconductor device 200 according to the implementations of the present disclosure, by providing a gate isolating trench 250 between the channel column array 230 and the dummy channel column array 240, it effectively avoids the problem that the dummy channel columns 241 are deformed due to the attraction force of the charges in the transition channel columns 231 to the dummy channel columns 241, resulting in the leakage current of the semiconductor device 200 and affecting the performance of the semiconductor device 200.

Provided is a semiconductor device. The semiconductor device includes a substrate, stacked layers, a transition channel column array, a dummy channel column array, and a gate isolating trench.

The stacked layers are formed on the substrate by alternately stacking insulating layers and gate layers. Along a first lateral direction parallel to the substrate, the stacked layers are divided into a transition channel column region and a dummy channel column region that is located beside the transition channel column region.

The transition channel column array is formed in the stacked layers and is located in the transition channel column region, and includes multiple transition channel columns arranged in an array in the first lateral direction and in a second lateral direction that is parallel to the substrate and perpendicular to the first lateral direction.

The dummy channel column array is formed in the stacked layers and is located in the dummy channel column region, and includes multiple dummy channel columns arranged in an array in the first lateral direction and the second lateral direction.

The gate isolating trench is formed in the stacked layers and extends along the second lateral direction, and is formed between the transition channel column array and the dummy channel column array.

In some implementations, the multiple dummy channel columns are formed in a stair-step region of the stacked layers.

In some implementations, the gate isolating trench may include multiple gate isolating trenches arranged at intervals along the first lateral direction, and an arrangement density of the multiple gate isolating trenches gradually decreases in the direction from the transition channel column array to the dummy channel column array.

In some implementations, the gate isolating trench may include multiple gate isolating trenches arranged at intervals along the second lateral direction to form a dotted line shape.

In some implementations, the semiconductor device may further include a gate line slit that penetrates through the stacked layers in a longitudinal direction perpendicular to the substrate and extends along the first lateral direction.

In some implementations, a material of the gate isolating trench may be same as a material of the gate line slit.

In some implementations, a cross-sectional shape of the gate isolating trench in the first lateral direction may include at least one of a rectangle, a trapezoid, or a semicircular shape, and a surface of the gate isolating trench facing the dummy channel column array may be planar.

In some implementations, an arrangement density of the multiple transition channel columns in the transition channel column array may gradually decrease towards the dummy channel column array along the first lateral direction.

In some implementations, each of the multiple transition channel columns may have a critical dimension that is a distance from a center of the transition channel column to an edge of the transition channel column. Critical dimensions of the multiple transition channel columns may gradually increase towards the dummy channel column array along the first lateral direction.

In another aspect, the implementations of the present disclosure further provide a method for preparing a semiconductor device. The method includes the following steps.

A substrate is provided.

Stacked layers are formed. The stacked layers are formed on the substrate by alternately stacking insulating layers and gate layers. Along a first lateral direction parallel to the substrate, the stacked layers are divided into a transition channel column region and a dummy channel column region that is located beside the transition channel column region.

A transition channel column array is formed. The transition channel column array is formed in the stacked layers, is located in the transition channel column region, and includes multiple transition channel columns arranged in an array in the first lateral direction and in a second lateral direction that is parallel to the substrate and perpendicular to the first lateral direction.

A dummy channel column array is formed. The dummy channel column array is formed in the stacked layers, is located in the dummy channel column region, and includes multiple dummy channel columns arranged in an array in the first lateral direction and the second lateral direction.

A gate isolating trench is formed. The gate isolating trench is formed in the stacked layers, extending along the second lateral direction, and is formed between the transition channel column array and the dummy channel column array.

In addition to the above implementations, the implementations of the present disclosure may also have other implementations. All technical solutions formed by equal replacements or equivalent replacements shall fall within the protection scope claimed by the implementations of the present disclosure.

In summary, although implementations of the present disclosure have been disclosed as above, they are not intended to limit the present disclosure. A person of ordinary skill in the art can make various changes and modifications without departing from the spirit and scope of the implementations of the present disclosure, and therefore, the protection scope of the implementations of the present disclosure is subject to the scope defined by the claims.

1. A semiconductor device, comprising:
stacked layers, wherein the stacked layers comprise insulating layers and gate layers that are alternately stacked along a longitudinal direction and extending in a first lateral direction and a second lateral direction, wherein the first lateral direction and the second lateral direction are perpendicular to each other and are both perpendicular to the longitudinal direction;
a channel column array in the stacked layers, wherein the channel column array comprises a plurality of channel columns arranged in the first lateral direction and the second lateral direction;
a dummy channel column array in the stacked layers, wherein the dummy channel column array comprises a plurality of dummy channel columns arranged in the first lateral direction and the second lateral direction; and
a gate isolating trench in the stacked layers, wherein the gate isolating trench extends between the channel column array and the dummy channel column array along the second lateral direction.

2. The semiconductor device according to claim 1, wherein the channel column array comprises transition channel columns arranged along the first lateral direction and storage channel columns arranged along the first lateral direction, the transition channel columns are located between the storage channel columns and the dummy channel column array, and a critical dimension of the transition channel columns is larger than a critical dimension of the storage channel columns.

3. The semiconductor device according to claim 1, wherein the dummy channel columns are located in a stair-step region of the stacked layers.

4. The semiconductor device according to claim 1, wherein the gate isolating trench comprises a plurality of gate isolating trenches arranged at intervals along the first lateral direction, and an arrangement density of the plurality of gate isolating trenches gradually decreases in a direction from the channel column array to the dummy channel column array.

5. The semiconductor device according to claim 1, wherein the gate isolating trench comprises a plurality of isolating trenches arranged at intervals along the second lateral direction in a dotted line shape.

6. The semiconductor device according to claim 1, further comprising a gate line slit penetrating through the stacked layers in the longitudinal direction and extending along the first lateral direction.

7. The semiconductor device according to claim 6, wherein a material of the gate isolating trench is same as a material of the gate line slit.

8. The semiconductor device according to claim 1, wherein a cross-sectional shape of the gate isolating trench in the first lateral direction comprises at least one of a rectangle, a trapezoid, or a semicircular shape, and a surface of the gate isolating trench facing the dummy channel column array is planar.

9. The semiconductor device according to claim 2, wherein an arrangement density of the transition channel columns in the channel column array gradually decreases towards the dummy channel column array along the first lateral direction.

10. The semiconductor device according to claim 9, wherein each of the transition channel columns has a critical dimension from a center of each of the transition channel columns to an edge of each of the transition channel columns, and the critical dimension of each of the transition channel columns gradually increases towards the dummy channel column array along the first lateral direction.

11. A method for preparing a semiconductor device, comprising:
providing a substrate;
forming stacked layers on the substrate by alternately stacking insulating layers and gate layers along a longitudinal direction, wherein the insulating layers and gate layers extend along a first lateral direction and a second lateral direction, wherein the first lateral direction and the second lateral direction are perpendicular to each other and are both perpendicular to the longitudinal direction;
forming a channel column array in the stacked layers, wherein the channel column array comprises a plurality of channel columns arranged in the first lateral direction and the second lateral direction;
forming a dummy channel column array in the stacked layers, wherein the dummy channel column array comprises a plurality of dummy channel columns arranged in the first lateral direction and the second lateral direction; and
forming a gate isolating trench in the stacked layers, wherein the gate isolating trench extends between the channel column array and the dummy channel column array along the second lateral direction.
